(19) United States
(12) Patent Application Publication
(10) Pub. No.: US 2026/0126503 A1
(43) Pub. Date: May 7, 2026

(54) Field Synthesizer Devices with Shim Arrays for Control of Magnetic Fields

(71) Applicant: ViBo Health Inc., Los Angeles, CA (US)

(72) Inventors: Gil Travish, Los Angeles, CA (US); Geoffrey Gao, Los Angeles, CA (US)

(21) Appl. No.: 19/378,954

(22) Filed: Nov. 4, 2025

Related U.S. Application Data
(60) Provisional application No. 63/715,808, filed on Nov. 4, 2024.

(51) Int. Cl. G01R 33/3875; H01F 7/06

(52) U.S. Cl. CPC G01R 33/3875; H01F 7/064

(57) ABSTRACT

Field synthesizer devices utilizing shim arrays for control of magnetic fields in accordance with embodiments of the invention are disclosed. In one embodiment, a field synthesizer device for local control of a magnetic field within a region of interest (“ROI”) is provided, comprising: a first array comprising a plurality of electromagnets; a second array comprising a plurality of electromagnets; at least one current controller configured to provide electric current to the plurality of electromagnets of the first and second arrays; a processor and a memory storing a program comprising instructions that, when executed by the processor, cause the field synthesizer device to: calculate shimming field data; calculate gradient field data; generate the shimming field and the at least one gradient field using the first and second arrays; and wherein the shimming field and the at least one gradient field combine for local control of a magnetic field within the ROI.

### CROSS-REFERENCE TO RELATED APPLICATION

The current application claims priority to U.S. Provisional Patent Application No. 63/715,808, filed on Nov. 4, 2024, the disclosure of which is incorporated herein by reference.

### FIELD OF THE INVENTION

The present invention generally relates to magnetic fields and more specifically to field synthesizers having shim arrays for control of magnetic fields.

### BACKGROUND

Magnets have been constructed for many applications ranging from audio speakers to MRI machines and generators. Magnets have been made from exotic materials, simple wire coils, wrapped foil (to lower inductance), super conducting cables, etched circuit board patterns, etc. A distinction may be made between permanent magnets formed from magnetized materials and electromagnets which require current to produce a field. Further, a distinction may be made between continuous (“DC”) magnets and pulsed magnets.

Generally, magnetic resonance is a process by which a physical excitation (resonance) is set up via magnetism. This process was used to develop magnetic resonance imaging (“MRI”) and nuclear magnetic resonance (“NMR”) spectroscopy technology. An MRI may provide an anatomic image and magnetic resonance spectroscopy (“MRS”) may provide a tissue composition analysis related to underlying dynamic physiology.

Typically, NMR describes a physical phenomenon in which nuclei in a strong constant magnetic field are perturbed by a weak oscillating magnetic field and respond by producing an electromagnetic signal with a frequency characteristic of the magnetic field at the nucleus. This process generally occurs near resonance, when the oscillation frequency matches the intrinsic frequency of the nuclei, which depends on the strength of the static magnetic field, the chemical environment, and the magnetic properties of the isotope involved. NMR spectroscopy may be used for various applications and NMR is also routinely used in advanced medical imaging techniques, such as in MRI.

### BRIEF DESCRIPTION OF THE DRAWINGS

The various embodiments of the present field synthesizer devices comprising shim arrays (may also be referred to simply as “field synthesizer devices”) now will be discussed in detail with an emphasis on highlighting the advantageous features. These embodiments depict the novel and non-obvious field synthesizer devices shown in the accompanying drawings, which are for illustrative purposes only. These drawings include the following figures:

FIG. 1 is a block diagram illustrating a system for field synthesizer devices in accordance with an embodiment of the invention;

FIG. 2 is a block diagram illustrating a client device in accordance with an embodiment of the invention;

FIG. 3 is a block diagram illustrating a field synthesizer device that includes shim arrays in accordance with an embodiment of the invention;

FIG. 4 is a block diagram illustrating a server in accordance with an embodiment of the invention;

FIG. 5 is a diagram illustrating a first array of electromagnets and a second array of electromagnets (may also be referred to as “field synthesizer arrays” (“FSA”) or “shim arrays”) (e.g., a “paired coil array”) in accordance with an embodiment of the invention;

FIG. 6 is a diagram illustrating generating of a gradient at a region of interest (“ROI”) via magnetic fields using a paired coil array in accordance with an embodiment of the invention;

FIG. 7A is a diagram illustrating a linear x-gradient generated by a paired coil array in accordance with an embodiment of the invention;

FIG. 7B is a diagram illustrating a resulting magnetic field due to a superposition of a main field B₀ and the x-gradient generated by a paired coil array in accordance with an embodiment of the invention;

FIG. 8 is a block diagram illustrating another field synthesizer device that includes shim arrays in accordance with an embodiment of the invention;

FIG. 9 is a diagram illustrating a ROI, sub-regions, and associated fields in accordance with an embodiment of the invention;

FIG. 10 is a diagram illustrating field distribution as a function of one axis in accordance with an embodiment of the invention;

FIG. 11 is a diagram illustrating various volumes in accordance with an embodiment of the invention;

FIG. 12 is a diagram illustrating an ideal main field B₀ and a ROI in accordance with an embodiment of the invention;

FIG. 13 is a diagram illustrating a main field B₀ and a ROI in accordance with an embodiment of the invention;

FIG. 14 is a diagram illustrating a main field B₀, ROI, a sub-volume, and correction fields in accordance with an embodiment of the invention;

FIG. 15 is a diagram illustrating a main field B₀, ROI, a sub-volume, and correction fields after application of shimming fields in accordance with an embodiment of the invention;

FIG. 16 is a diagram illustrating a main field B₀, ROI, a sub-volume, and correction fields after application of shimming fields and a gradient field in accordance with an embodiment of the invention;

FIG. 17 is a diagram illustrating anti-shimming fields in a main field B₀, ROI, a sub-volume, and correction fields after application of shimming fields and a gradient field in accordance with an embodiment of the invention; and

FIG. 18 is a diagram illustrating another field synthesizer device in accordance with an embodiment of the invention.

### SUMMARY OF THE INVENTION

The various embodiments of the present field synthesizer devices utilizing shim arrays for control of magnetic fields contain several features, no single one of which is solely responsible for their desirable attributes. Without limiting the scope of the present embodiments, their more prominent features will now be discussed below. After considering this discussion, and particularly after reading the section entitled “Detailed Description,” one will understand how the features of the present embodiments provide the advantages described here.

In a first aspect, a field synthesizer device for local control of a magnetic field within a region of interest (“ROI”) is provided, the field synthesizer device comprising: a first array comprising a plurality of electromagnets; a second array comprising a plurality of electromagnets, wherein the second array is positioned opposite and parallel to the first array; at least one current controller configured to provide electric current to the plurality of electromagnets of the first array and to the plurality of electromagnets of the second array; a processor operatively connected to the at least one current controller; memory storing a program comprising instructions that, when executed by the processor, cause the field synthesizer device to: calculate shimming field data for generating a shimming field within a ROI; calculate gradient field data for generating at least one gradient field within the ROI; generate the shimming field, within the ROI, using the first and second arrays; and generate the at least one gradient field, within the ROI, using the first and second arrays; and wherein the shimming field and the at least one gradient field combine for local control of a magnetic field within the ROI.

In an embodiment of the first aspect, each electromagnet of the first array comprises an independently powered coil.

In another embodiment of the first aspect, each electromagnet of the second array comprises an independently powered coil.

In another embodiment of the first aspect, the field synthesizer device further comprises a primary magnet configured to generate a main field B_{0.}

In another embodiment of the first aspect, the first and second arrays are positioned laterally to the primary magnet.

In another embodiment of the first aspect, the program comprises further instructions that, when executed by the processor, cause the field synthesizer device to: calculate anti-shimming field data for generating at least one anti-shimming field outside of the ROI; and generate the at least one anti-shimming field, outside of the ROI, using the first and second arrays.

In another embodiment of the first aspect, the shimming field and the at least one gradient field are generated parallel to the main field B₀.

In another embodiment of the first aspect, the shimming field and the at least one gradient field produce a z-component that alters the main field B₀.

In another embodiment of the first aspect, the shimming field data is calculated based on a pre-calculated shim field and a correction factor.

In another embodiment of the first aspect, the gradient field data is calculated based on a spatial filtering component and a pulse sequence component.

In another embodiment of the first aspect, the shimming field is generated by: selecting a first subset of electromagnets in the first array and a second subset of electromagnets in the second array; determining, using the shimming field data, a current level for each electromagnet in the first subsets of electromagnets; determining, using the shimming field data, a current level for each electromagnet in the second subsets of electromagnets; and applying the current levels to each electromagnet in the first and second subsets of electromagnets causing the first and second arrays to generate the shimming field.

In another embodiment of the first aspect, the at least one gradient field is generated by: selecting a first subset of electromagnets in the first array and a second subset of electromagnets in the second array; determining, using the gradient field data, a current level for each electromagnet in the first subsets of electromagnets; determining, using the gradient field data, a current level for each electromagnet in the second subsets of electromagnets; and applying the current level to each electromagnet in the first and second subsets of electromagnets causing the first and second arrays to generate the at least one gradient field.

In another embodiment of the first aspect, the plurality of electromagnets of the first array use the electric current to generate a first gradient field.

In another embodiment of the first aspect, the electric current is used to activate and set a polarity to NORTH for a first electromagnet of the plurality of electromagnets of the first array.

In another embodiment of the first aspect, the electric current is used to activate and set a polarity to SOUTH for a second electromagnet of the plurality of electromagnets of the first array.

In another embodiment of the first aspect, the plurality of electromagnets of the second array use the electric current to generate a second gradient field.

In another embodiment of the first aspect, the electric current is used to activate and set a polarity to SOUTH for a first electromagnet of the plurality of electromagnets of the second array.

In another embodiment of the first aspect, the electric current is used to activate and set a polarity to NORTH for a second electromagnet of the plurality of electromagnets of the second array.

In another embodiment of the first aspect, the plurality of electromagnets of the first and second arrays comprises a plurality of solenoids.

In another embodiment of the first aspect, each of the plurality of solenoids is wound around an iron core or other magnetic material.

### DETAILED DESCRIPTION OF THE DRAWINGS

The following detailed description describes the present embodiments with reference to the drawings. In the drawings, reference numbers label elements of the present embodiments. These reference numbers are reproduced below in connection with the discussion of the corresponding drawing features. The embodiments of the present field synthesizer devices for control of magnetic fields within a region or interest (“ROI”) and/or a volume of interest (“VOI”) (ROI and VOI may be used interchangeable herein) are described below with reference to the figures. In various embodiments, a ROI may be a sample within a data set identified for a particular purpose. For example, a ROI may be boundaries on an image (or in a volume) that may be measured, analyzed, etc. These figures, and their written descriptions, may indicate that certain components of the apparatus are formed integrally, and certain other components are formed as separate pieces. Those of ordinary skill in the art will appreciate that components shown and described herein as being formed integrally may in alternative embodiments be formed as separate pieces. Those of ordinary skill in the art will further appreciate that components shown and described herein as being formed as separate pieces may in alternative embodiments be formed integrally. Further, as used herein the term integral describes a single unitary piece.

In the fields of NMR and MRS, material composition analysis is performed. Typically, these spectrometers use a magnetic field to align the spins within a sample, and then the aligned spin populations are perturbed with radiofrequency (“RF”) pulses. The response of the sample to these pulses, also an RF signal, is indicative of atomic and molecular composition. The response is also a function of the environment surrounding the sample as well as the magnetic field properties. Spatial filtering is typically used in MRS where biological samples are complex and there is a design to measure the composition of a sub-volume. In NMR, spatial filtering is not typically used as samples are homogeneous.

One aspect of the present embodiments includes the realization that to produce the best (e.g., the narrowest line widths and highest signal-to-noise ratios) spectral responses within NMR high-homogeneity, magnetic fields are required. Generally, inhomogeneous magnetic fields cause broadening and amplitude reduction of the spectral peaks, and can also lead to additional background signal which adds to the “noise.” Correcting magnetic fields to the levels demanded by NMR spectroscopy is technically demanding and can add significant cost to a system. For example, typical magnetic field homogeneity specifications can be <20 parts per million (ppm). For biological samples, as is the default for MRS, a higher homogeneity is usually sufficient because the sample itself produces magnetic non-uniformities on the order of 10 ppm.

Another aspect of the present embodiments includes the realization that, at the same time, “spatial filtering,” (i.e., the process of selecting specific sub-volumes by encoding spatial coordinates with magnetic field gradients) typically requires “gradient coils.” These gradient coils can be highly complex electromagnets designed to take up minimal space in the limited open bore of the magnet as possible and yet produce high fields that can be rapidly adjustable. These coils further complicate a machine and increase costs and space constraints. For a machine designed to cover the entire body and operating in imaging mode, gradient coils are often a preferred option. However, for settings where the VOI is small and/or imaging is not a primary consideration, other field manipulations methods become possible. Often, these alternative field generating solutions have not been considered as MRI gradient-coils dominate the design approaches.

Another aspect of the present embodiments includes the realization that in small systems (e.g., benchtop systems) that require field gradients, conventional solutions can be difficult to deploy due to the limited bore space. In addition, the power supplies often needed to operate gradient coils can be large and expensive. This combination of technical challenges means that while shimming and gradient coils are often conceptually simple, they are complex and expensive to implement in practice. In various embodiments, the term “shimming” may refer to the process of fine-tuning signal resolution by optimizing the magnetic field homogeneity.

The present field synthesizer devices also consider methods of manipulating the fields inside of NMR and MRS magnets. For example, methods of combining both the shimming and gradient functions within the VOI and anti-shimming fields outside the VOI are provided. In addition, while the present field synthesizer devices are capable of generating an arbitrary field within a ROI, specific applications place demands on the device which are not generally addressable by a generic magnetic field generating system. Specifically, the need to combine field shimming with field gradients means that local control of the field in more than one axis is typically required. In the context of increasing the signal to noise through spatial filtering, the present embodiments also seek to create “anti-shimming” fields surrounding the VOI.

As typically deployed in conventional NMR and MRS systems, shimming involves correcting field inhomogeneities within a measurement volume. It is usually taught that the specific geometry of the magnet or the VOI can be used as a symmetry basis and corrections are spatial modes in that basis. Specifically, spherical harmonics are often useful as are cylindrical ones. Electromagnetic coils are then places to allow for correction of the first N harmonics. For instance, a state of the art NMR might have as many as 40 coils used to correct 8th order harmonics within a measurement volume. In an NMR, such corrections are often needed because the field errors need to be in the parts per billion. Alternatively, in the MRI/MRS applications, the VOI is much larger, yet the correction demanded is much cruder and can be measured in parts per million. With large primary magnet volumes, the shimming coils often have the same cylindrical symmetry and seek to only correct the lowest order harmonics. Thus, the shape and placement of the shim coils mimics the primary magnet design (to preserve symmetries) and seeks fine field control. Gradient coils, on the other hand, are more typically found in MRI/MRS machines. NMR machines typically have no or one-axis of gradient coils. In all cases the gradient coils tend to produce relatively large field gradients across the volume of interest. In the case of MRI/MRS, the gradient coils must typically be adjusted quickly to allow for imaging. As an example, in an MRI, an image volume may include 512×512×512≈134 million voxels. The ability to gather these large data sets on time scales that patients can lie still for requires very rapid field gradient adjustments. Thus, the functions and field provided, and rates of control for shimming and gradient coils are very different from one another. Hence, in conventional systems, it is taught that these two field control systems should be separated.

The present field synthesizer devices utilize arrays of electromagnets (e.g., coil arrays) as an alternative to conventional approaches. For example, by using a pair of parallel coil arrays, positioned laterally to the main magnet (may also be referred to as the “primary magnet”), it is possible to create arbitrary field profiles within a VOI. The present field synthesizer devices allow for various features including, but not limited to, a large active area (the arrays can be extended to cover larger volumes and gaps allowing for active volumes with a length scale the order of ½ the array gap), partially open active area (since the arrays may be planar and well separated, access to the active area is largely unimpeded and allows for samples, coils, circuits and cabling to easily be brought in and out of the active area), high field amplitudes (since the coils can be made larger (and taller) and have higher electric currents (may also be referred to as “currents”) that run through them, fields considerably higher than flat windings or wires can be produced, multiple simultaneous active regions (it is possible to synthesize two or more simultaneous regions which have the desired field profile. This may be particularly useful for having one calibration region and one sample region undergoing parallel measurements), anti-shimming of adjacent areas (since it is possible to produce fields which have a desired field in one sub-volume while having a field that suppresses resonance in surrounding volumes. Such a configuration may work to improve the signal to noise), generation of unusual or complex field profiles (since the entire array can be activated to produce a field, complex field configurations may be possible to produce. Such field configurations may be advantageous for spatial filtering or for use with as yet to be invented pulse configurations.), resolution (fine grained control of the field and generation of multiple simultaneous active areas can be enabled through a higher density of coils and optimized coil arrangements (e.g., sunflower arrays)).

Turning now to the drawings, field synthesizer devices utilizing shim arrays for control of magnetic fields in accordance with embodiments of the invention are described. In many embodiments, field synthesizer devices may be configured to scan a user's finger for non-invasive health tracking. In various embodiments, field synthesizer devices may utilize the control of magnetic fields to track individual health patterns in a compact (e.g., a table-top) instrument. For example, field synthesizer devices may be configured for NMR or MRS applications by generating shim and gradient fields in a ROI and anti-shimming fields surrounding the ROI, as further described below.

In many embodiments, field synthesizer devices may include arrays of electromagnets configured for localized control of fields within a ROI utilizing shimming fields, one or more gradient fields, and anti-shimming fields. In some embodiments, field synthesizer devices may include a primary magnet configured to generate a main field (may also be referred to as a “primary field”) B₀. In some embodiments, field synthesizer devices may include a first array of electromagnets (e.g., a first coil array) and a second array of electromagnets (e.g., a second coil array), where the second array is positioned opposite and parallel to the first array. In some embodiments, field synthesizer devices may be configured to calculate shimming field data for generating a shimming field within the ROI and calculate gradient field data for generating at least one gradient field within the ROI, as further described below. In some embodiments, the shimming field and the at least one gradient field may combine to create a field profile for local control within a ROI. In addition, field synthesizer devices may be configured to generate anti-shimming fields surrounding the ROI for additional advantages, as further described below.

In various embodiments, field synthesizer devices may also include one or more current controllers for control of the electromagnets. For example, each individual electromagnet may be powered by a current controller, as further described below. In some embodiments, the individual electromagnets may be a solenoid having a wire wound around a core made from a magnetic material such as, but not limited to, iron. By controlling specific groups of electromagnets, the field synthesizer devices may allow for localized control of fields within a ROI utilizing shimming fields, one or more gradient fields, and anti-shimming fields.

The principle of operation of the present field synthesizer devices includes the realization that, for a given point in space and for a given field configuration, it is possible to calculate (via analytical or numerical methods) a suitable set of currents for each coil in the arrays that will produce the desired outcome (e.g., shimming fields, gradient fields, and anti-shimming fields). Limitations may come from the pitch (i.e., spacing) of the coils, maximum current the coils can withstand, and the maximum fields that can be produced. Additional limitations may come from geometry as only certain field components can be excited by a parallel array of coils. However, because coils can be asymmetrically excited and because of edge fields, there exists a diversity of field configurations achievable, as further described below. Further, thermal management may be considered. For example, temperature variations impact magnetic fields, especially for permanent magnets, and can also impact coils through changes in resistance. Various thermal management methods may be utilized including those known in the arts. The present embodiments may seek to ensure that repeated use of coils produces the same field. In some embodiments, this may be achieved by using current controlled power supplies (as opposed to voltage controlled), and/or by properly heat sinking the coil arrays to ensure a similar temperature range after repeated use. Considerations for calculating and generating shimming, gradient, and anti-shimming fields in accordance with embodiments of the invention are further described below.

### Considerations for Shimming, Gradient, and Anti-Shimming Fields

As provided herein, a field can be controlled over one voxel, and ideally over the surrounding voxels. The present embodiments consider how the two demands on the field generation—shimming and gradient—can be calculated. In many embodiments, the shimming component may be based on two factors: a first component that is a pre-calculated shim field which may be a result of a detailed calibration and a second component that is a correction factor based on “auto-shimming” algorithms. The first component may be established at a factory and/or at time of initialization, manufacture, production, etc. and, from time to time, in the field during maintenance calibrations. This first component is intended to establish a baseline and at least give the system a reasonable starting point under ideal conditions (factory temperature, humidity, etc.). The second component may be calculated in-line at least once per day or at every power cycle (first turn on), and maybe performed as frequently as between every user. There are a wide variety of “auto-shimming” approaches which generally rely on making small changes to the shim field and measuring a specific spectral line width or similar diagnostic to determine if the shim improved. For example, the present embodiments may utilize a sample that is automatically inserted into the test volume each time a user completes a scan. For the avoidance of confusion: the shim field is usually established as an overall optimization of the field; however, in general field synthesizer devices may create an array of shim fields for an array of sub-volumes. In the simplest form, we could divide the test volume into a set of sub-volumes (e.g., 10 along what would be the finger). We could establish an optimal shim for each sub-volume. This could be performed through any of moving the sample; moving the coil; using a gradient to do spatial filtering or simply only activating specific field synthesizer coils.

In some embodiments, field synthesizer devices utilizing shim arrays) may perform an internal calibration sequence, both at factory initialization and periodically in normal use, to ensure reproducible field synthesis. During calibration, the magnetic response of each electromagnet (or coil element) may be characterized under known current conditions to generate a baseline field matrix stored in non-volatile memory. Subsequent verification steps may use a reference region to measure any drift in the generated field relative to the stored baseline. In some embodiments, either a standardized phantom or a designated calibration coil can enhance the calibration process. The processor then computes updated correction coefficients (ΔB or ΔI) and adjusts the corresponding drive currents accordingly. In short, this may allow the system to re-establish absolute field accuracy and homogeneity without external measurement equipment and, by definition, maintains long-term stability even under varying thermal or mechanical conditions.

In various embodiments, having established the shim field, the gradient field may be established from two distinct components: 1) spatial filtering; and, 2) part of the pulse sequence. The spatial filtering component may be straightforward: only the voxel or voxels of interest need be on-resonance. The present embodiments may not actually encode location with field, as is traditionally done. Instead, the present embodiments are filtering out all other volumes. For component 1 (i.e., spatial filtering), we need not have a distinct field component; simply that the voxel of interest is ensured to be on-resonance and, ideally, that all other voxels are “pushed away” from resonance either through anti-shimming or a similar “wrong field.” In many embodiments, an anti-shimming field may refer to a locally opposed magnetic field region configured to attenuate signal response outside the ROI. For component 2 (i.e., part of the pulse sequence), for each type of pulse sequence, a specific gradient or gradients may be called for. These gradients can be complex time sequences which are designed to rotate or otherwise manipulate the spin orientations. Again, these types of gradients need only be applied over one sub-volume at a time and we can “take time” between sub-volume measurements to allow for the samples to recover (reach equilibrium).

In the present field synthesizer devices, the combination of shimming and gradients is possible here whereas it is not generally possible in conventional MRI/MRS systems. The present embodiments seek to control the field over a small, voxel sized, volume; not the entire imaging or measurement volume. Here, we seek to measure volumes which might be divided into order of 10×10×10=1000 voxels. Thus, the present embodiments may be measuring approximately 100,000 times less data than in a conventional system (e.g., a conventional imaging MRI). Therefore, the present embodiments allow for changing the field on a much slower time scale (e.g., milliseconds or even longer) compared to MRI that may be in the microseconds and the present embodiments we do not require that the gradient be generated across an entire “slice” at once (since speed is not a primary consideration). In addition, because the present embodiments are concerned with spectra over image data, we can optimize the field distribution to obtain a single voxel's spectrum, pause, and then take a second one, etc. Systems for field synthesizer devices in accordance with embodiments of the invention are further described below.

### Systems for Field Synthesizer Devices

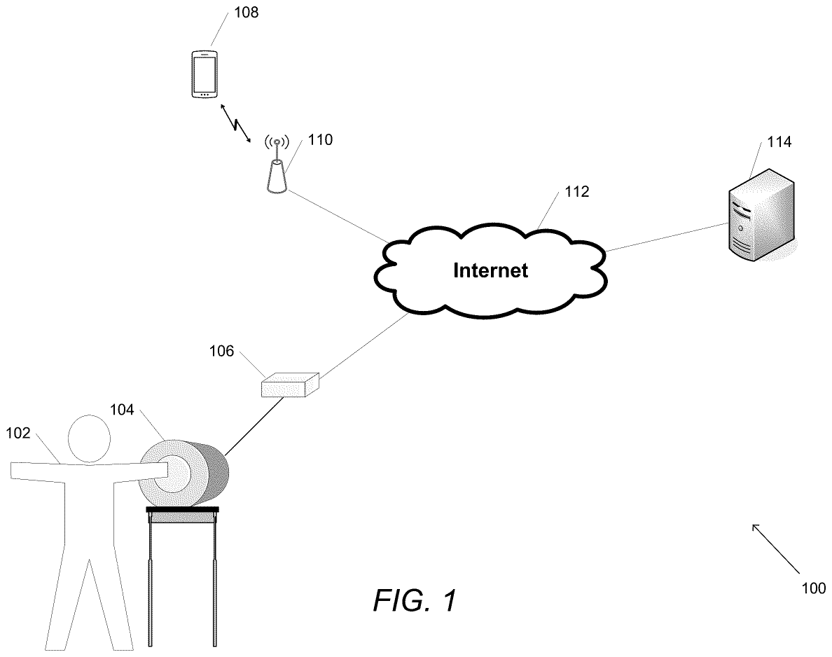

A block diagram illustrating a system for field synthesizer devices in accordance with an embodiment of the invention is shown in FIG. 1. A system 100 may include a user 102 who may be scanned using a field synthesizer device 104. For example, the user 102 may be scanned by placing a finger in the field synthesizer device 104. In some embodiments, the field synthesizer device 104 may include a user interface that provides instructions to the user for scanning. In some embodiments, the user interface may also provide various information to the user 102 including, but not limited to, health tracking information. In many embodiments, the system 100 may also include a client device 108. In some embodiments, the client device 108 may be utilized to allow the user 102 to create an account, interface with health tracking information, etc. In several embodiments, the client device 108 may include various electronic devices, such as, but not limited to, a desktop computer, laptop computer, tablet computer, smartphone, etc.

In reference to FIG. 1, the client device 108 and the field synthesizer device 104 may be connected to, and have access to, the Internet 112 in a manner known to one of ordinary skill in the art. For example, the field synthesizer device 104 may access the Internet 112 using a variety of methods such as, but not limited to, a modem and/or router 106 (and/or a wireless access point). Further, the client device 108 may access the Internet 112 via a wireless access point 110, such as, but not limited to, Wi-Fi (and/or using a modem and/or router). In some embodiments, the field synthesizer device(s) 104 and/or the client device 108 may access the Internet 112 using a cellular network. The system 100 may also include one or more servers 114 in communication with the field synthesizer device 104 and/or the client device 108. In some embodiments, the field synthesizer device 104 may be configured to transmit scan data to the server 114 and/or the client device 108. In some embodiments, the scan data may be utilized to generate health data (e.g., overall health measurement, energy level, nutrient levels, blood sugar levels, etc.). In many embodiments, health data may also include insights, recommendations, suggestions, etc.

In further reference to FIG. 1, the field synthesizer device 104 may be configured to generate shimming fields, one or more gradient fields, and anti-shimming fields using shim arrays, as further described below. In some embodiments, local field optimizations may be performed by the field synthesizer device 104. In some embodiments, local field optimizations may be performed by the server 114. In some embodiments, local field optimizations may be performed by any combination of the field synthesizer device 104 in conjunction with the server 114.

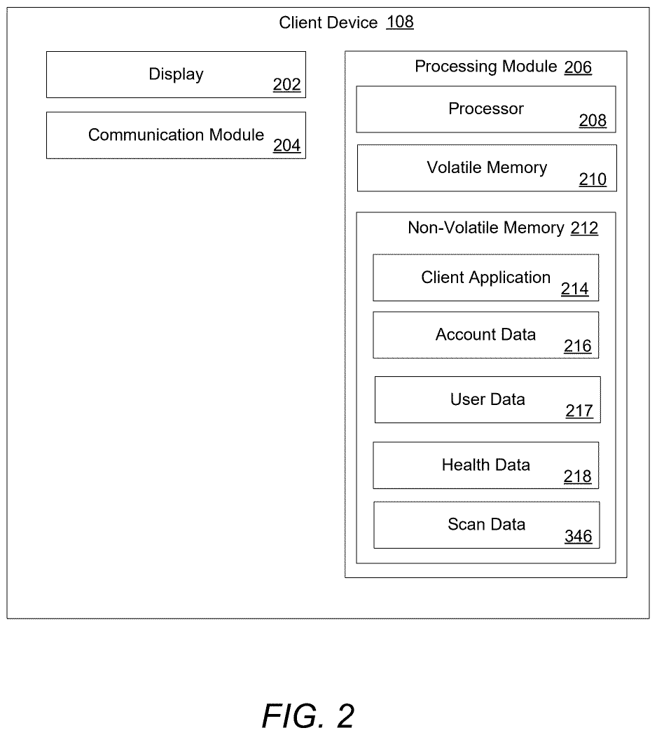

A block diagram illustrating a client device in accordance with an embodiment of the invention is shown in FIG. 2. The client device 108 may include a display 202 and a communication module 204. In many embodiments, the client device 108 may also include a processing module 206 that may include a processor 208, a volatile memory 210, and a non-volatile memory 212. In various embodiments, the non-volatile memory 212 may include a client application 214 that allows the client device 108 be in network communication with the server 114 and/or the field synthesizer device 104. In some embodiments, the client device 108 may provide a user interface for allowing a user to set up and manage an account using account data 216 (e.g., user e-mail, username, password, log-in frequency, etc.). In some embodiments, the client device 108 device may store the account data 216. In addition, the client device 108 may also collect, generate, and/or store user data 217. For example, the user data 217 may include various data associated with the user such as, but not limited to, personal identification information (e.g., user name, date of birth, phone number, etc.), banking information, payment history information, etc. In many embodiments, the data (e.g., account data 216 and user data 217) may be inputted by the user using a touch interface, a keypad interface, voice interface, etc. In various embodiments, the user data 217 and/or the account data 216 may be transmitted to the server 114 using the communication module 204.

In reference to FIG. 2, the client device 108 may receive scan data using the communication module 204 from the field synthesizer device 104 and/or the server 114. In some embodiments, the client device 108 may also receive health data 218 using the communication module 204 from the field synthesizer device 104 and/or the server 114. In some embodiments, health data 218 may be generated at the client device 108 using various data including, but not limited to, the scan data 346. As described herein, health data may include any information that may be utilized to track and optimize a user's health. For example, health data may include an overall health measurement, energy level, nutrient levels, blood sugar levels, trends, insights, recommendations, suggestions, background information on health conditions, etc.

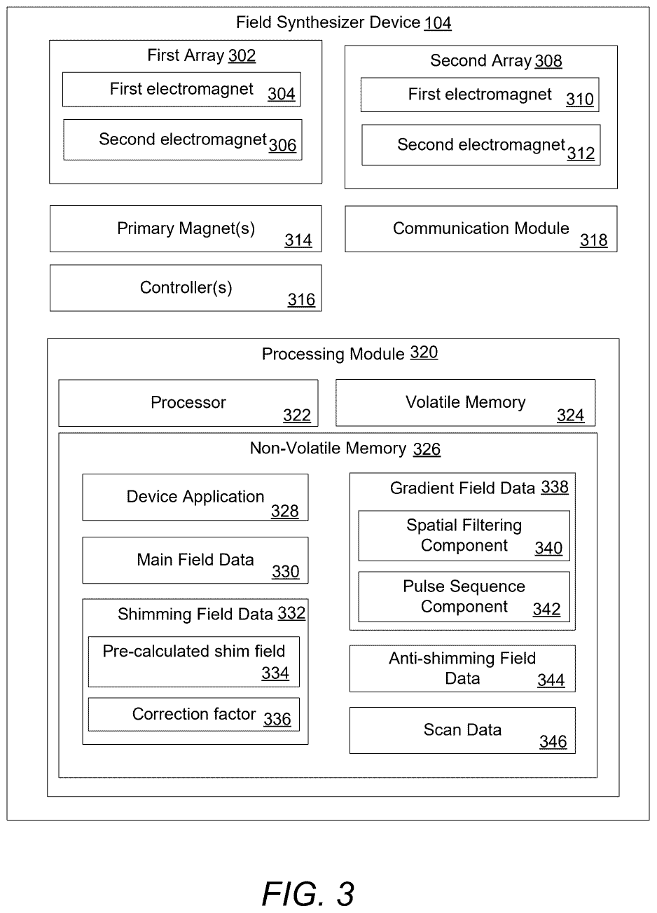

A block diagram illustrating a field synthesizer device that includes shim arrays in accordance with an embodiment of the invention is shown in FIG. 3. The field synthesizer device 104 may include a first array 302 comprising a plurality of electromagnets (e.g., first electromagnet 304 and second electromagnet 306, etc.), a second array 308 comprising a plurality of electromagnets (e.g., a first electromagnet 310 and a second electromagnet 312). In many embodiments, the first and second arrays 302, 308 may be positioned opposite and parallel to each other, as further described below. Although the field synthesizer device 114 is illustrated as having two arrays, a field synthesizer device may include any number of arrays having any number of electromagnets as appropriate to the requirements of a specific application in accordance with embodiments of the invention.

In reference to FIG. 3, the field synthesizer device 104 may also include one or more primary magnet(s) 314 and one or more controller(s) 316 such as, but not limited to, current controller(s), as further described below. In some embodiments, the primary magnet 314 may be a primary magnet assembly having two or more primary magnets. In some embodiments, the controller 316 may allow for control of the electromagnets (e.g., the first and second 304, 306 electromagnets of the first array 302 and the first and second electromagnets 310, 312 of the second array 308) in generating various fields such as, but not limited to, shimming fields, at least one gradient fields, and/or anti-shimming fields, as further described herein. In some embodiments, the field synthesizer device 104 may include a communication module 318 for access to the Internet or for wireless communication with various devices, such as, but not limited to, a user device 108, a server 114, cloud storage, etc.

In further reference to FIG. 3, the field synthesizer device 104 may also include a control panel (may also be referred to as a “processing module”) 320 that may include a processor 322, a volatile memory 324, and a non-volatile memory 326. In various embodiments, the non-volatile memory 326 may include a device application 328 that configures the field synthesizer device 104 to generate a field within a region of interest, as further described herein. For example, the field synthesizer device 104 may be configured to calculate shimming field data 332 for generating a shimming field within a ROI. In some embodiments, the shimming field data 332 may be calculated based on a pre-calculated shim field 334 and a correction factor 336, as further described herein. In addition, the field synthesizer device 104 may be configured to calculate gradient field data 338 for generating at least one gradient field within a ROI. In some embodiments, the gradient field data 338 may be calculated based on a spatial filtering component 340 and a pulse sequence component 342, as further described herein. Further, the field synthesizer device 104 may be configured to calculate anti-shimming field data for generating one or more anti-shimming fields surrounding the ROI, as further described herein. In addition, the field synthesizer device 104 may be configured to capture scan data 346, as further described below. Scan data 346 may include various data such as, but not limited to, NMR or MRS data depending on the configuration of the field synthesizer device 104.

As is well known in the art, the use of mathematical basis functions—such as spherical harmonics, Legendre polynomials, or other orthogonal expansions—may provide a convenient framework for representing complex magnetic field distributions. In the present embodiments, such functions may be utilized to decompose the measured or desired field map into component terms that correspond to the independent control vectors of the coil arrays. In many embodiments, the resulting coefficient set may define the drive currents for each electromagnet to generate the composite shimming, gradient, or anti-shimming field. For example, the processor 322 may effectively solve a weighted inverse problem, projecting the target field onto the available basis to determine the optimal current distribution for the region of interest.

In some embodiments, during normal operation, the field synthesizer device 104 may update its coil calibration values using data from the most recent field verification. Each coil has a stored relationship between current and magnetic field strength, and small changes in this relationship may be corrected by comparing the expected and measured fields. In some embodiments, the processor 332 adjusts the corresponding drive coefficients so that subsequent calculations reflect the true field behavior of the arrays (e.g., the first and second arrays 302, 308). In short, this may allow the system to maintain accurate field generation over time without requiring external recalibration.

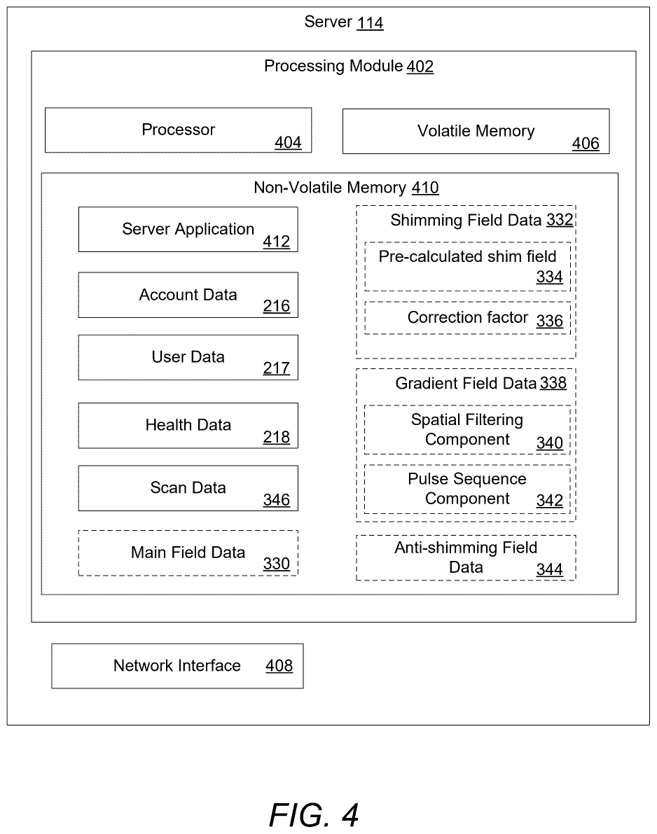

A block diagram illustrating a server in accordance with an embodiment of the invention is shown in FIG. 4. The server 114 may include a processing module 402 that may include a processor 404, a volatile memory 406, network interface 408, and a non-volatile memory 410. In many embodiments, the non-volatile memory 410 may include a server application 412 that configures the processor 404 to provide functionalities to the field synthesizer device 104 and/or the client device 108, as further described herein. For example, the server 114 may be configured to send to, and/or receive from, various data (e.g., account data 216, user data 217, health data 218, scan data 346, etc.) with the field synthesizer device 104 and/or the client device 108 using the network interface 408, as further described herein.

In reference to FIG. 4, in some embodiments, the server 114 may also be configured to receive from, and/or send to, the field synthesizer device 104, field data (e.g., main field data 330, shimming field data 332, gradient field data 338, anti-shimming field data 344) with the field synthesizer device 104, as further described herein. In some embodiments, the server 114 may be configured to generate and/or update the field data. However, in some embodiments, the field data may be generated and/or updated at the field synthesizer device 104 without the assistance of the server 114.

In reference to FIGS. 2-4, the various components including, but not limited to, the processing modules are represented by separate boxes. The graphical representations depicted in each of FIGS. 2-4 are merely examples and are not intended to indicate that any of the various components of the client device, field synthesizer device, and/or server are necessarily physically separate from one another, although in some embodiments they might be. In some embodiments, however, the structure and/or functionality of any or all components of the client device, field synthesizer device, and/or server may be combined. In some embodiments, the processors may include, but is not limited to, any generic processing unit capable of performing computations. The volatile memories may include, but is not limited to, Randomly Accessed Memory (RAM) or another comparable form of rapid storage. Non-volatile memories may include, but is not limited to, any memory type that retains storage of data after powering down. In addition, in some embodiments, the communication modules and/or network interface may include their own processors, volatile memories, and/or non-volatile memories. In addition, the communication modules and/or network interface may comprise, but are not limited to, one or more transceivers and/or wireless antennas (not shown) configured to transmit and receive wireless signals such as (but not limited to) satellite, radio frequency (RF), Bluetooth or WIFI. In other embodiments, the communication modules and/or network interface may comprise (but are not limited to) one or more transceivers configured to transmit and receive wired signals.

Although specific systems, client devices, field synthesizer devices, and servers are discussed above with respect to FIGS. 1-4, any of a variety of client devices, field synthesizer devices, and servers, communicating using various communication protocols as appropriate to the requirements of a specific application can be utilized in accordance with embodiments of the invention. Further, in some embodiments, field synthesizer devices can retrofit existing permanent-magnet NMR devices. Field synthesizer arrays in accordance with embodiments of the invention are discussed further below.

### Field Synthesizer Arrays

Field synthesizer devices described herein are intended to generate both shim and gradient fields for a benchtop NMR or MRS application. The device may include configurations of electromagnets which partially surround a VOI. The magnets and their configuration are designed to produce an arbitrary field at one or more locations within the VOI. While many configurations are contemplated, the basic approach is a pair of arrays of electromagnets set apart by a gap that is at least as wide as the VOI's width.

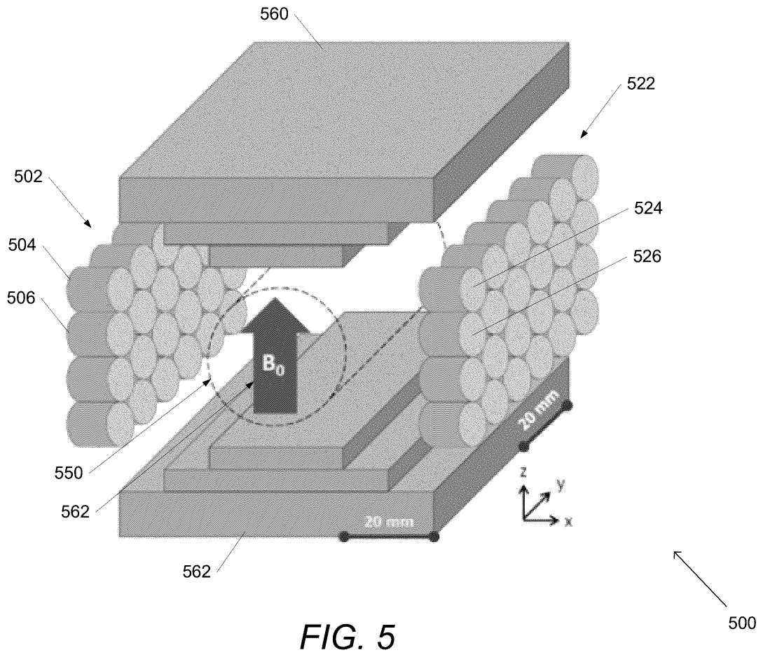

A diagram illustrating a first array of electromagnets and a second array of electromagnets (may also be referred to as “field synthesizer arrays” or “FSAs” or “shim arrays”) for field synthesizer devices in accordance with an embodiment of the invention. In reference to FIG. 5, the field synthesizer device 500 may include a first array 502 of electromagnets and a second array 522 of electromagnets. For example, the first array 502 may include a first electromagnet 504, a second electromagnet 506, and so on. Likewise, the second array 522 may include a first electromagnet 524, a second electromagnet 526, and so on. In many embodiments, the first and second arrays 502, 522 may form a so called “paired coil array.” Further, the first array 502 may form a so called “coil wall” and the second array 522 may also form a coil wall.

For example, FIG. 5 depicts a paired coil array that includes two 6-by-4 (as used herein, array dimensions list the number of columns first, followed by the number of rows) coil walls (i.e., the first and second arrays 502, 524), where each coil wall is made up of 24 electromagnets (e.g., 24 solenoids). The solenoids (may also be referred to as “coils”) may be various sizes such as, but not limited to, 5 mm in radius and 10 mm in length. In various embodiments, the configuration of the arrays and/or the electromagnets provides for optimization. For example, the column-row combination depicted in FIG. 5 was selected to allow for greater gradient control and finer localization along a finger that may be inserted into finger cavity (may also be referred to a “bore”) 550 (represented by the hollow cylinder) of the field synthesizer device 500.

In reference to FIG. 5, a general configuration of the paired coil array is illustrated with a primary magnet assembly having a first primary magnet 560 and a second primary magnet 562. In some embodiments, the primary magnet(s) 560, 562 may be posited laterally to the first and second arrays 502, 522. In some embodiments, the primary magnet 560 may generate a main field B₀ 562, as further described below. In some embodiments, the primary magnet(s) 560, 562 may form an H-magnet assembly as illustrated and may be a primary dipole magnet. It should be noted that the representation illustrated in FIG. 5 has removed implementation details for clarity. For example, no power supplies nor connecting wires are shown. Further, the shim arrays (i.e., the first and second arrays 502, 522) in FIG. 5 are shown on a square grid (equal pitch in both axis); however, it is possible to have staggered (e.g., triangular) grids or more complex arrangements (e.g. sunflower) of solenoids.

In many embodiments, a building block of the FSA is the individual electromagnet. Various configuration of electromagnet may be deployed as part of the FSA. For example, in some embodiments, a solenoid may be utilized as the electromagnet, where the solenoid includes a wire wound around a core made from a magnetic material such as, but not limited to, iron. In various embodiments, the individual electromagnet may be powered by a current controller (e.g., a power supply). In general, the power supply may be bipolar to allow for either polarity of magnetic fields to be generated from each solenoid. Various other electromagnets may be utilized in accordance with embodiments of the invention, including, but not limited to, flexible circuits, multi-layer PC boards, foil windings, etc. Further, various sizes of coils may be utilized depending on the characteristic of the primary magnet and the overall device configuration. For example, in some embodiments, the coil size may include a 1 cm outer diameter coil which may be wound on a 5 mm core. In some embodiments, larger sizes than may be utilized for large devices. Further, smaller solenoids can also be contemplated.

In various embodiments, the individual FSA may include a set of solenoids on a common frame with or without a yoke that provides for directing an “unproductive” field (i.e., a field that is not in the VOI). In some embodiments, the FSA may comprise solenoids on a square, triangular or more complicated grid. For example, the FSA may be a 4×5 array of 1 cm solenoids on a 1 cm pitch. This array could be larger or smaller depending on the VOI and the primary magnet.

As described herein, the field synthesizer device may include one or more FSAs. For example, in some embodiments, the field synthesizer device may include two FSAs. In other embodiments, the field synthesizer device may include four FSAs. The spacing between FSAs is dependent on the overall system geometry. For instance, it may be desirable to clear the primary magnet yokes which may necessitate a specific spacing. FSAs that are separated by more than one or two times the length scale of the array (e.g., a length or a width) can produce sub-optimal results due to 3D effects and fridge fields, but may still be of utility. In many embodiments, FSAs may have a separation set to 1-1.5 times the shorter dimension of the individual FSA. For the previous example of a 4 cm×5 cm FSA, the gap would then be 4-6 cm.

In addition, the solenoids may be connected to individual current controllers or power supplies. For example, the current controllers may be supplied from a common bus with individual controllers located adjacent to the solenoid, thus allowing for less current to flow throughout the entire circuit. Alternatively, each solenoid may be directly connected to an individual power supply. The details of the power circuits, connections and controls will depend on the overall performance requirements. As an example, consider the aforementioned 1 cm coils operating at 1 amp and a few volts each. For the exemplary array, 20 current controllers may be utilized and a total of 40 for the full device. The overall power requirements may be significant, however, in practice there may be a limit on how many coils are simultaneously activated at full current. For instance, it may only require 4 or perhaps 8 coils to be activated at once to achieve a typical shim and gradient fields. In addition, these coils need not necessarily be run at full current. Then, the typical total current requirement might be 4×0.5 amps+4×0.25 amp=3 amps.

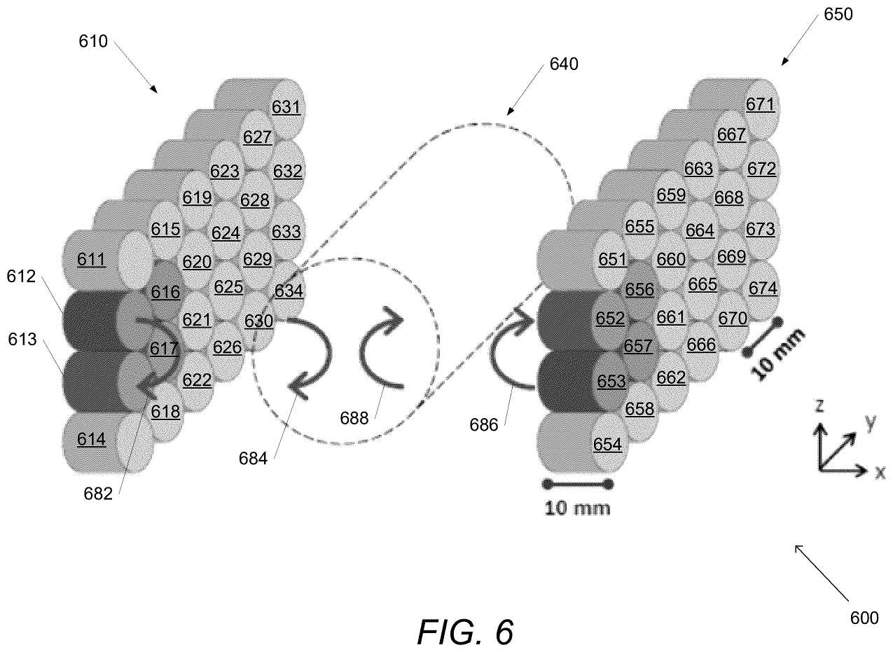

A diagram illustrating generating of a gradient at a ROI via magnetic fields using a paired coil array in accordance with an embodiment of the invention is shown in FIG. 6. In reference to FIG. 6, the field synthesizer device 600 may include a first array 610 of electromagnets and a second array 650 of electromagnets. In some embodiments, the first and second arrays 610, 650 may be coil walls, as further described above. In some embodiments, the first array 610 may be a 6-by-4 coil wall that includes 24 electromagnets (e.g., 24 solenoids or coils). For example, the first array 610 may include a first solenoid 611, a second solenoid 612, a third solenoid 613, a fourth solenoid 614, a fifth solenoid 615, a sixth solenoid 616, a seven solenoid 617, an eighth solenoid 618, a ninth solenoid 619, a tenth solenoid 620, an eleventh solenoid 621, a twelfth solenoid 622, a thirteenth solenoid 623, a fourteenth solenoid 624, a fifteenth solenoid 625, a sixteenth solenoid 626, a seventeenth solenoid 627, a eighteenth solenoid 628, a nineteenth solenoid 629, a twentieth solenoid 630, a twenty-first solenoid 631, a twenty-second solenoid 632, a twenty-third solenoid 633, and a twenty-fourth solenoid 634.

Likewise, the second array 650 may be a 6-by-4 coil wall that includes 24 electromagnets (e.g., 24 solenoids or coils). For example, the second array 650 may include a first solenoid 651, a second solenoid 652, a third solenoid 653, a fourth solenoid 654, a fifth solenoid 655, a sixth solenoid 656, a seven solenoid 657, an eighth solenoid 658, a ninth solenoid 659, a tenth solenoid 660, an eleventh solenoid 661, a twelfth solenoid 662, a thirteenth solenoid 663, a fourteenth solenoid 664, a fifteenth solenoid 665, a sixteenth solenoid 666, a seventeenth solenoid 667, a eighteenth solenoid 668, a nineteenth solenoid 669, a twentieth solenoid 670, a twenty-first solenoid 671, a twenty-second solenoid 672, a twenty-third solenoid 673, and a twenty-fourth solenoid 674.

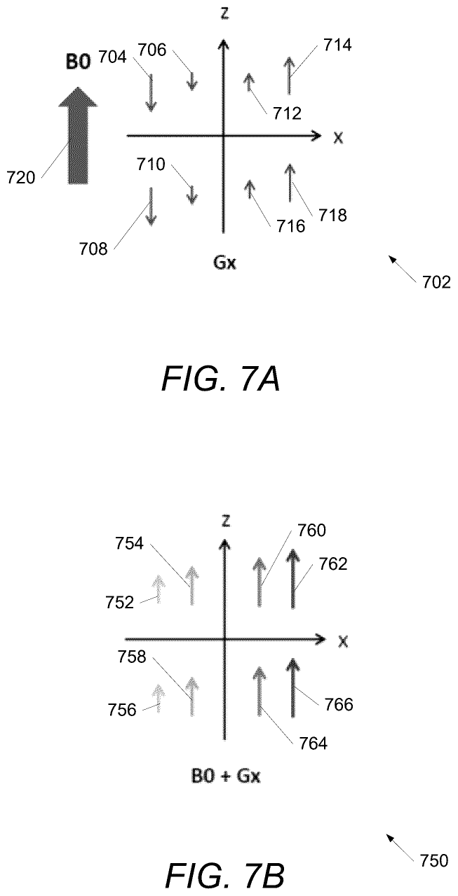

In further reference to FIG. 6, a paired coil array 610, 650 with active solenoids to generate a gradient along the x-axis at a ROI near the lower end of the bore is provided. The arrows 682, 684, 686, 688 represent magnetic fields that generate the gradient (may also be referred to as the “gradient generating magnetic fields” or “gradient fields”). For example, the gradient generating magnetic fields may include one or more gradient generating magnetic field(s) generated by the electromagnets of the first array 610 (e.g., the first gradient generating magnetic fields 682, 684 of the first array) and one or more gradient generating magnetic field(s) generated by the electromagnets of the second array 650 (e.g., the first gradient generating magnetic fields 686, 688 of the second array 650). Note, the primary magnet assembly has been removed to allow for better viewing. In many embodiments, the individual solenoids may be controlled to generate various gradients. In some embodiments, one or more solenoids may be turned on in such a way as to generate a specified gradient. For example, as illustrated in FIG. 6, solenoids may be turned on to generate an x-gradient. In the first array 610, the second solenoid 612 and the sixth solenoid 616 may be active (ON) coils for a first polarity (e.g., NORTH) and the third solenoid 613 and the seventh solenoid 617 may be active (ON) coils for a second polarity (e.g., SOUTH) generating the gradient generating magnetic fields 682, 684. Further, in the second array 650, the second solenoid 652 and the sixth solenoid 656 may be active (ON) coils for the second polarity (e.g., SOUTH) and the third solenoid 653 and the seventh solenoid 657 may be active (ON) coils for first polarity (e.g., NORTH) generating the gradient generating magnetic fields 686, 688. In various embodiments, the remaining other solenoids may be OFF during gradient synthesis. It may be predicted that this particular configuration of the solenoids will create a closed magnetic circuit from NORTH to SOUTH, generating the gradient (see FIG. 7A) as the synthesized fields curve through the finger. In some embodiments, magnetometers of various designs are contemplated to measure the magnetic field and for use in a closed loop control. For instance, Hall probes are useful to profile the magnetic field. An NMR system with a small volume sample and coil can also serve as a highly accurate probe.

A diagram illustrating a linear x-gradient 702 generated by a paired coil array in accordance with an embodiment of the invention is shown in FIG. 7A. In FIG. 7A, the arrows 704, 706, 708, 710, 712, 714, 716, 718 represent the linear x-gradient 702 generated by the solenoid configuration in FIGS. 5-6. The arrows 704, 706, 708, 710 are shown pointing SOUTH and the length of the arrows indicating relative strengths. Further, the arrows 712, 714, 716, 718 are shown pointing NORTH and the length of the arrows indicating relative strengths. The diagram also illustrates the main field B₀ 720 generated by the primary magnet assembly.

A diagram illustrating a resulting magnetic field 750 due to a superposition of a main field B₀ 720 and the x-gradient 702 generated by a paired coil array in accordance with an embodiment of the invention is shown in FIG. 7B. In FIG. 7B, the arrows 752, 754, 756, 758, 760, 762, 764, 766 represent the resulting magnetic field due to the superposition of B₀ 720 and the x-gradient 702. The resultant field 750 may be used to spatially encode B₀ 720 along the x-axis. During synthesis, it is typically assumed that a solenoid will only interact with its counterpart to produce a field. In actuality, there will be solenoid interactions that lead to unwanted modes which need to be eliminated.

Although specific FSAs and electromagnets are discussed above with respect to FIGS. 5-7B, any of a variety of FSAs and electromagnets as appropriate to the requirements of a specific application can be utilized in accordance with embodiments of the invention. Field synthesizer devices in accordance with embodiments of the invention are further described below.

### Field Synthesizer Devices

Although various configurations may be utilized, example field synthesizer devices may include a first array of electromagnets and a second array of electromagnets, where the second array may be disposed opposite and parallel to the first array. Field synthesizer devices may also include a set of current controllers, typically configured so that there is one controller per coil. Further, field synthesizer devices may either include or be in communication with a processing module that is pre-programmed (pre-calibrated) with configurations of currents that produce specific outputs or is able to calculate the necessary current configurations. In some embodiments, each solenoid within the arrays would typically be wound around a magnetic core (e.g., an iron core). In some embodiments, each array may have one or more sets of yokes desired to shunt the flux that would otherwise not contribute to field within the ROI. It should be noted that field synthesizer devices may be configured with additional arrays, for instance, four arrays (top, bottom, left and right) to allow for additional field configurations. Moreover, there may be additional elements that could be added to field synthesizer devices to enhance its capabilities, but which may not be inherently distinct in function. For instance, an overall pair of coils could be used to produce a larger field in one direction.

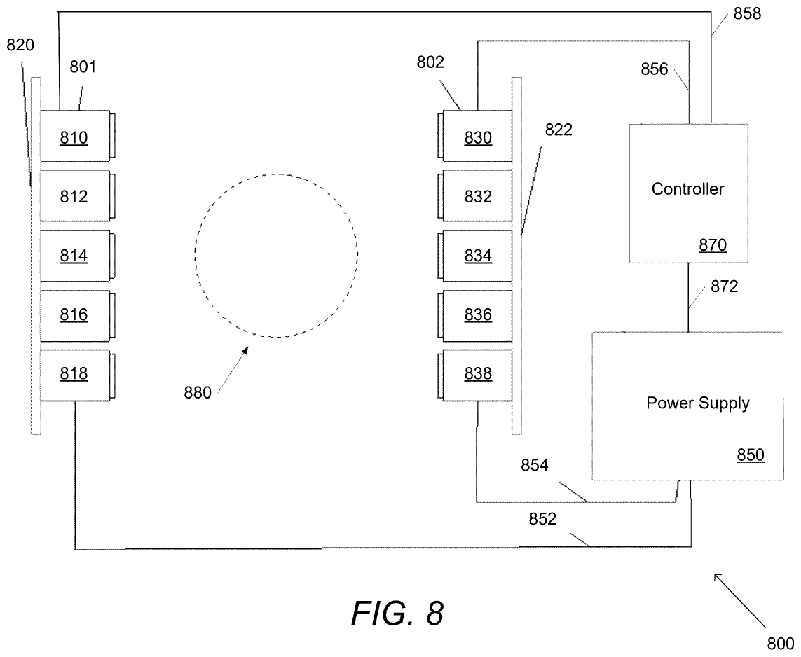

A block diagram illustrating another field synthesizer device that includes shim arrays in accordance with an embodiment of the invention is illustrated in FIG. 8. The field synthesizer device 800 may include a first array 820 having a plurality of electromagnets (e.g., a first electromagnet 810, a second electromagnet 812, a third electromagnet 814, a fourth electromagnet 816, and a fifth electromagnet 818) on a common substrate with each electromagnet having an independently powered coil (e.g., a first coil 801 for the first electromagnet 810 is illustrated). The coils (e.g., the first coil 801) may be driven by a current controlled power supply 850 connected via a wire to each of the plurality of electromagnets 810, 812, 814, 816, 818 of the first array 820 with independent channels (e.g., a wire 852 shown connecting the power supply 850 to the electromagnet 818). The field synthesizer device 800 may also include a controller 870 (e.g., a current controller) that may be connected to the power supply 850 via a connection 872. In some embodiments, the controller 870 may be connected to each of the plurality of electromagnets 810, 812, 814, 816, 818 of the first array 820 (e.g., a wire 858 shown connecting the controller 870 to the first electromagnet 810).

In reference to FIG. 8, the field synthesizer device 800 may also include a second array 822, positioned opposite the first array 820 and approximately symmetrically about a volume of interest 880. The second array 822 may also include a plurality of electromagnets (e.g., a first electromagnet 830, a second electromagnet 832, a third electromagnet 834, a fourth electromagnet 836, and a fifth electromagnet 838) each with its own coil (e.g., a first coil 802 for the first electromagnet 830 is illustrated). The coils (e.g., the first coil 802) may be driven by the current controlled power supply 850 connected via a wire to each of the plurality of electromagnets 830, 832, 834, 836, 838 of the second array 822 with independent channels (e.g., a wire 854 shown connecting the power supply 850 to the electromagnet 838). In some embodiments, the controller 870 may be connected to each of the plurality of electromagnets 830, 832, 834, 836, 838 of the second array 822 (e.g., a wire 856 shown connecting the controller 870 to the first electromagnet 830).

In many embodiments, field synthesizer devices may include two FSAs surrounding a primary magnet (e.g., a dipole permanent magnet). Each array may include several channels to allow for fine control. In some embodiments, individual current controllers may be connected to solenoids on a PC board allowing for digital control of the arrays. In some embodiments, the arrays may be spaced apart by less than two-times their width. Further, a controller may be pre-loaded with calibrations and algorithms that would allow for complex field control within the VOI.

For example, the field synthesizer device may include a dipole permanent magnet having a specific gap (e.g., 30 mm gap) and specific yokes (e.g., yokes that are 60 mm in diameter). Further, each FSA may have rows and columns of solenoids (e.g., a 5×5 array of 9 mm solenoids) on a pitch (e.g., a 10 mm pitch). Furthermore, each solenoid may be assumed to have a nominal operating current (e.g., 1 Amp) and a maximum safe operating limit (e.g., 2 Amps). Moreover, the solenoids may be connected to controllers (e.g., 50 total solenoids may each have independent bipolar +/−2 amp current controllers). In addition, the two FSAs may be separated (e.g., separated by just over 60 mm to clear the yokes). In various embodiments, the FSAs may each be backed by a nearly solid yoke plate.

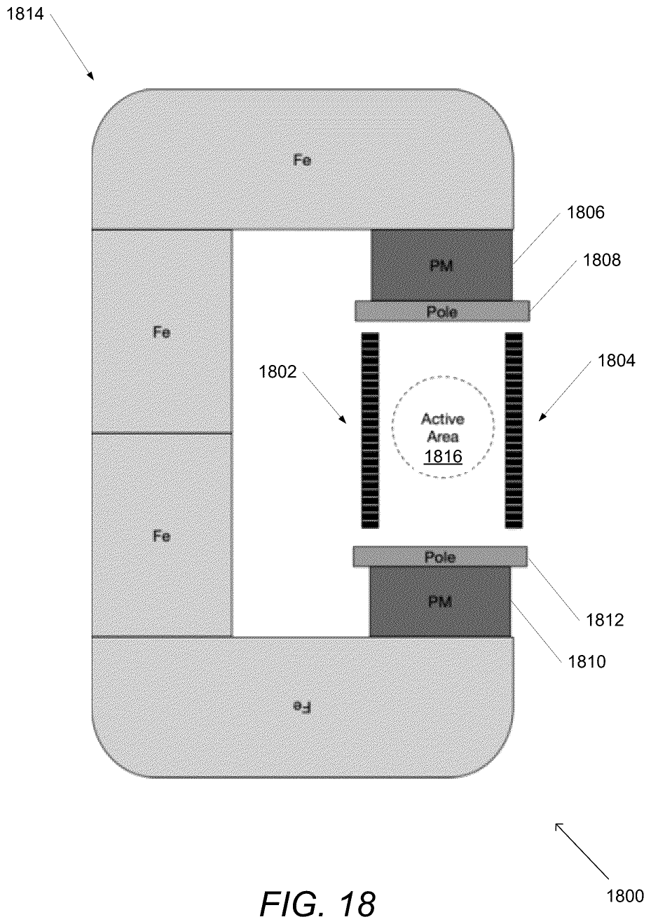

A diagram illustrating another field synthesizer device in accordance with an embodiment of the invention is shown in FIG. 18. The field synthesizer device 1800 may include a first array 1802 of electromagnets and a second array 1804 of electromagnets, as further described herein. In some embodiments, the field synthesizer device 1800 may also include a primary magnet assembly having a first primary magnet 1806 having a first pole 1808 and a second primary magnet 1810 having a second pole 1812. As further described herein, the first and second arrays 1802, 1804 and the primary magnet assembly 1806, 1810 may define an active area 1816 (e.g., a finger cavity). In some embodiments, the field synthesizer device 1800 may include a yoke 1814 may serve to help guide and/or concentrate magnetic flux. For example, the yoke 1814 may be a ferromagnetic structure (e.g., made of Fe) that connects the poles 1808, 1812 creating a closed magnetic circuit.

In various embodiments, the FSAs may first “auto shim” the magnet to produce the best line width on a calibration sample, and then sequences of gradient fields at different locations may be triggered to obtain a set of spectra at different locations within in the sample of interest (e.g., a finger). Further, field synthesizer devices may use the coils (e.g., the two coils) to obtain a calibration and signal on every scan, as further described below. In many embodiments, the field synthesizer device may produce equivalent shims and gradients at both coil locations, simultaneously, as further described below. More specifically, field synthesizer devices may always produce a shimming at the calibration location and use any drift information to compensate the scan obtained at the sample location on a shot-by-shot basis, as further described below.

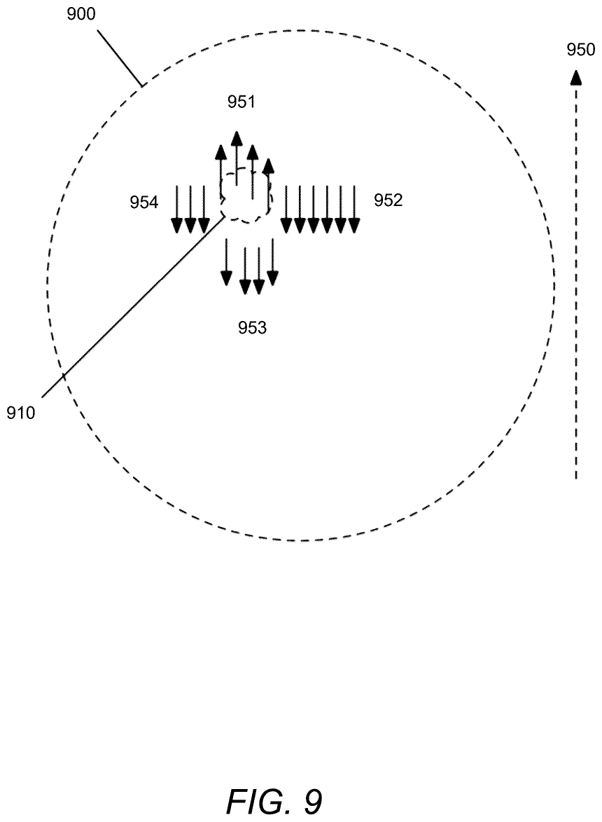

A diagram illustrating a ROI, sub-regions, and associated fields in accordance with an embodiment of the invention is shown in FIG. 9. The overall ROI 900 and a sub-region 910 are shown. The sub-region 910 may be irregularly shaped due to the interplay between the various factors that impact the spatial filtering. The primary magnetic field (i.e., main field) 950 also known as B₀ is shown. A shim or correction field 951 over the sub-region of interest 910 is shown. In addition, anti-shimming fields 952, 953, 954 surrounding the sub-region 910 are also illustrated.

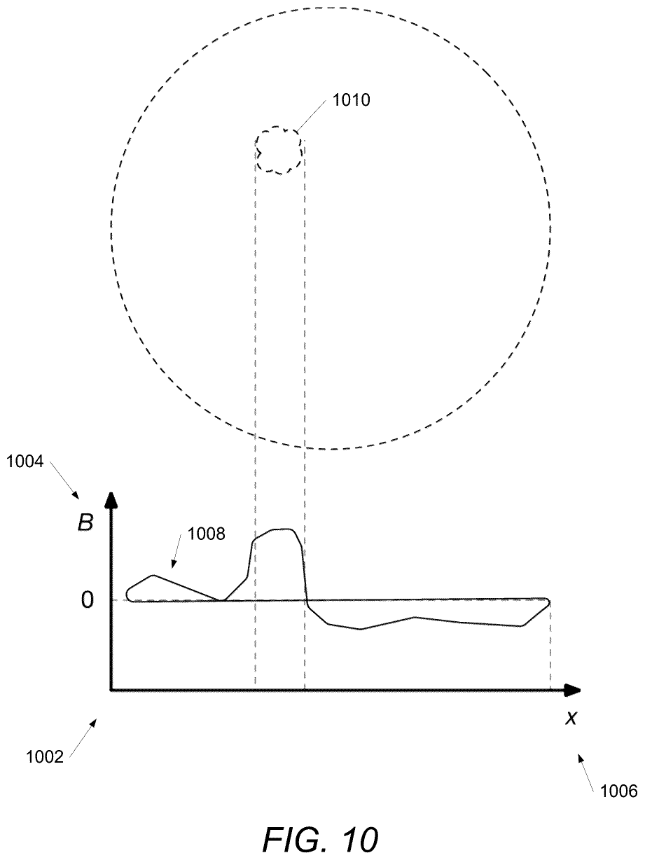

A diagram illustrating field distribution as a function of one axis in accordance with an embodiment of the invention is shown in FIG. 10. The diagram includes a graph 1002 illustrating the field distribution 1004 as a function of one axis 1006. Over the sub-region 1010, the magnetic field 1008 is positive and corrects for any local variation from the resonant ideal. In the surrounding area, the field is low or negative and acts as an “anti-shimming” field.

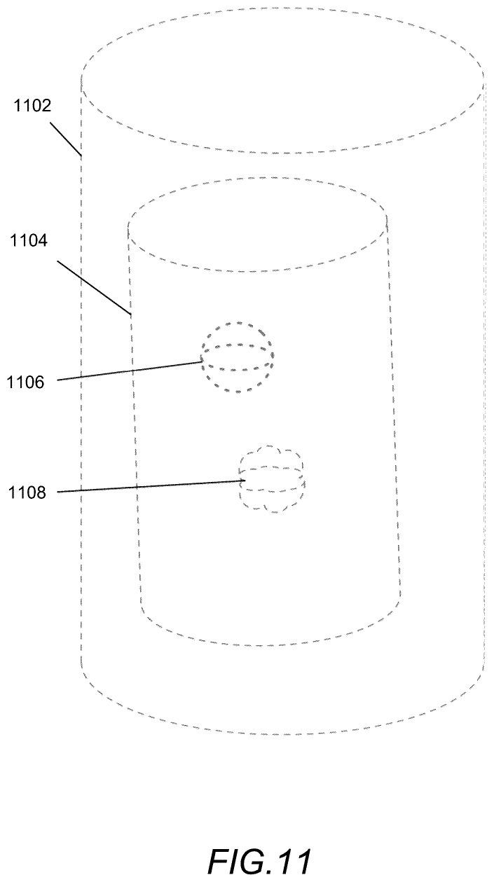

A diagram illustrating various volumes in accordance with an embodiment of the invention is shown in FIG. 11. FIG. 11 illustrates various volumes relevant to the problem at hand. The overall active volume 1102 extends beyond the volume of interest 1104 and due to non-ideal realizations of the system, is not, in general, colinear with the other volumes. An ideal sub-volume 1106, shown as a spherical region, is the volume which may be active at any one time. A more realistic region 1108 which may be distorted from the ideal by field variations, mechanical misalignments or variations in the target susceptibility is also illustrated.

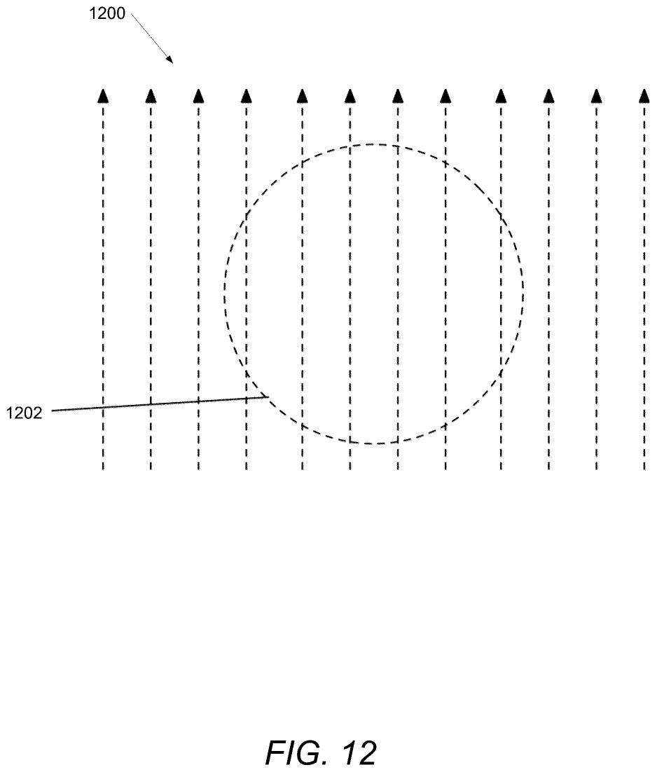

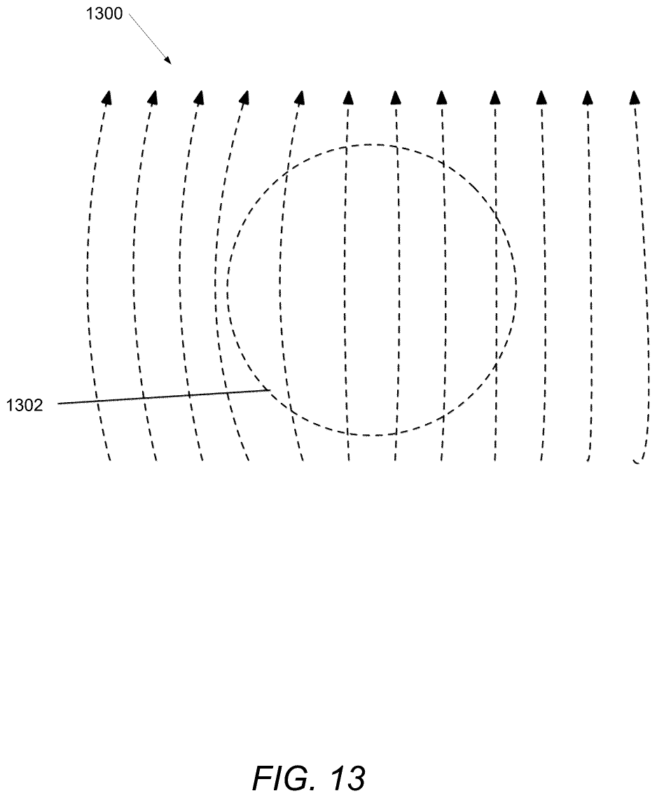

A diagram illustrating an ideal main field B₀ and a ROI in accordance with an embodiment of the invention is shown in FIG. 12. The ideal main field B₀ 1200 is shown together with the region of interest 1202. A realistic field would generally have edge effects and hence variations over a large, extended volume. A diagram illustrating another main field B₀ and a ROI in accordance with an embodiment of the invention is shown in FIG. 13. The more realistic main field, B₀ 1300 is shown together with the region of interest 1302. The variation in the field is exaggerated and varies both in the horizontal and vertical directions.

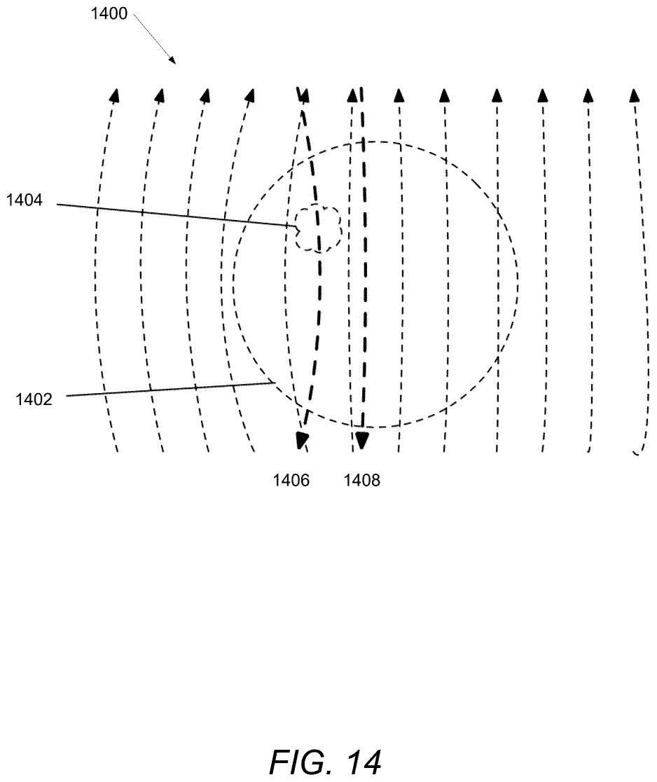

A diagram illustrating a main field B₀, ROI, a sub-volume, and correction fields in accordance with an embodiment of the invention is shown in FIG. 14. The more realistic main field B₀ 1400 together with the region of interest 1402 and the sub-volume 1404 is illustrated. The variation in the field is exaggerated and varies both in the horizontal and vertical directions. Further, correction fields 1406, 1408 are shown representationally.

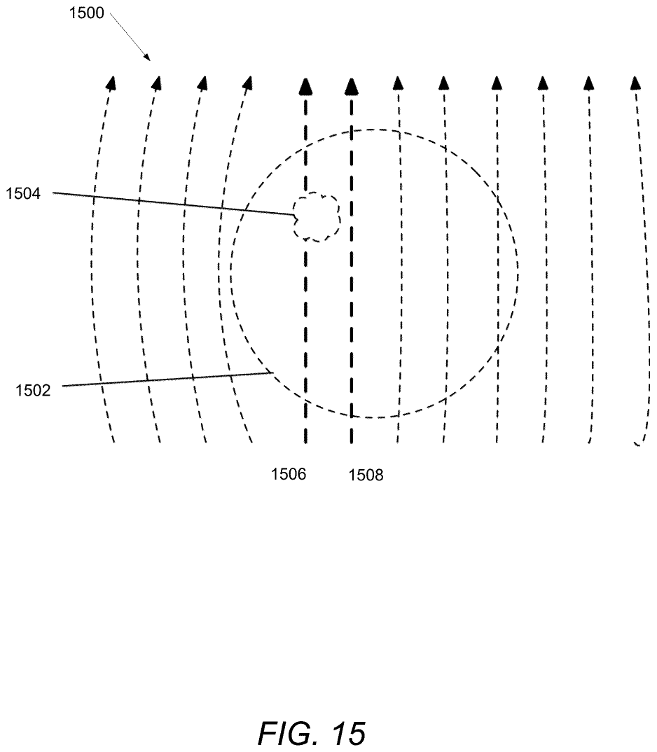

A diagram illustrating a main field B₀, ROI, a sub-volume, and correction fields after application of shimming fields in accordance with an embodiment of the invention is shown in FIG. 15. The more realistic main field B₀ 1500 is shown together with the ROI 1502 and the sub-volume 1504. The variation in the field is exaggerated and varies both in the horizontal and vertical directions. The corrected fields 1506, 1508, after application of the shimming fields to the previous FIG. 14, are shown.

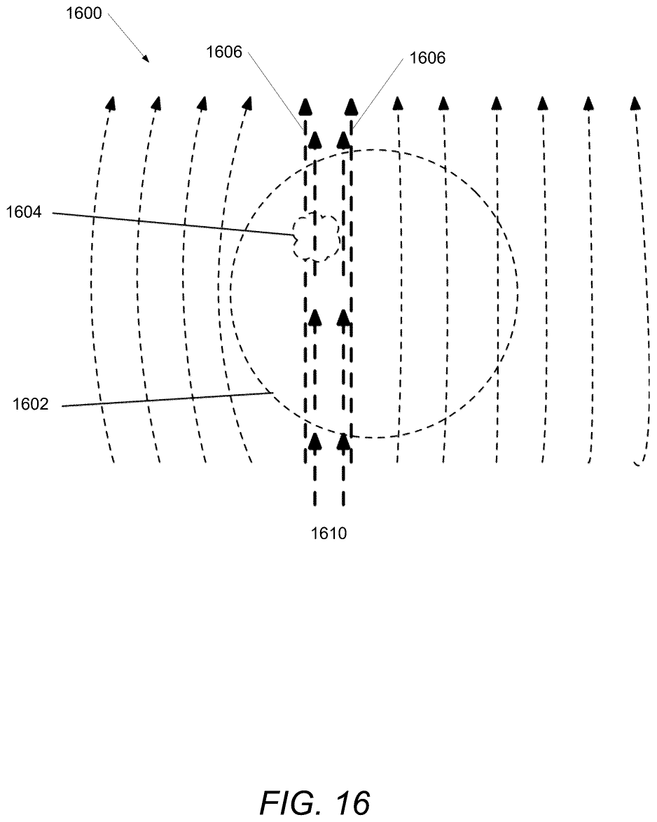

A diagram illustrating a main field B₀, ROI, a sub-volume, and correction fields after application of shimming fields and a gradient field in accordance with an embodiment of the invention is shown in FIG. 16. The more realistic main field B₀ 1600 is shown together with the ROI 1602 and the sub-volume 1604. The variation in the field is exaggerated and varies both in the horizontal and vertical directions. The corrected fields 1606, 1608, after application of the shimming fields, are shown. In addition, a gradient field 1610 has been applied. The gradient 1610 is in the direction of the primary field (i.e., main field B₀ 1600).

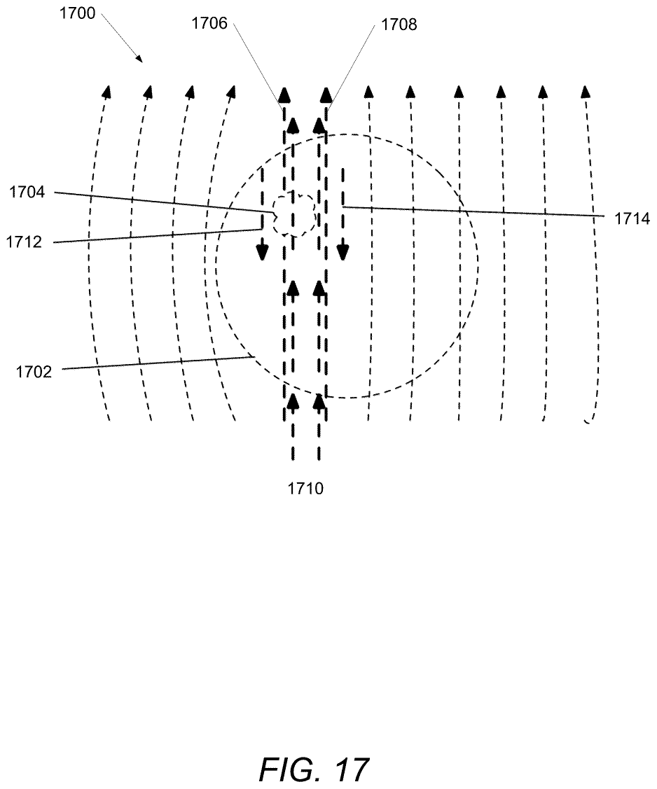

A diagram illustrating anti-shimming fields in a main field B₀, ROI, a sub-volume, and correction fields after application of shimming fields and a gradient field in accordance with an embodiment of the invention is shown in FIG. 17. The more realistic main field, B₀ 1700 is shown together with the ROI 1702 and the sub-volume 1704. The variation in the field is exaggerated and varies both in the horizontal and vertical directions. The corrected fields 1706, 1708, after application of the shimming fields, are shown. Further, a gradient field 1710 has been applied. The gradient 1710 is in the direction of the primary field (i.e., main field B₀ 1700). Anti-shimming fields 1712, 1714 are shown surrounding the sub-volume 1704. The anti-shimming fields may surround the sub-volume or only be applied to specific boundaries.

Although a specific field synthesizer devices and illustrative examples of various fields are discussed above with respect to FIGS. 8-17, any of a variety of field synthesizer devices and generation of various fields as appropriate to the requirements of a specific application can be utilized in accordance with embodiments of the invention. While the above description contains many specific embodiments of the invention, these should not be construed as limitations on the scope of the invention, but rather as an example of one embodiment thereof. It is therefore to be understood that the present invention may be practiced otherwise than specifically described, without departing from the scope and spirit of the present invention. Thus, embodiments of the present invention should be considered in all respects as illustrative and not restrictive.

What is claimed is:

1. A field synthesizer device for local control of a magnetic field within a region of interest (“ROI”), the field synthesizer device comprising:
a first array comprising a plurality of electromagnets;
a second array comprising a plurality of electromagnets, wherein the second array is positioned opposite and parallel to the first array;
at least one current controller configured to provide electric current to the plurality of electromagnets of the first array and to the plurality of electromagnets of the second array;
a processor operatively connected to the at least one current controller;
memory storing a program comprising instructions that, when executed by the processor, cause the field synthesizer device to:
calculate shimming field data for generating a shimming field within a ROI;
calculate gradient field data for generating at least one gradient field within the ROI;
generate the shimming field, within the ROI, using the first and second arrays; and
generate the at least one gradient field, within the ROI, using the first and second arrays; and
wherein the shimming field and the at least one gradient field combine for local control of a magnetic field within the ROI.

2. The field synthesizer device of claim 1, wherein each electromagnet of the first array comprises an independently powered coil.

3. The field synthesizer device of claim 2, wherein each electromagnet of the second array comprises an independently powered coil.

4. The field synthesizer device of claim 1 further comprising a primary magnet configured to generate a main field B_{0.}

5. The field synthesizer device of claim 4, wherein the first and second arrays are positioned laterally to the primary magnet.

6. The field synthesizer device of claim 5 wherein the program comprises further instructions that, when executed by the processor, cause the field synthesizer device to:
calculate anti-shimming field data for generating at least one anti-shimming field outside of the ROI; and
generate the at least one anti-shimming field, outside of the ROI, using the first and second arrays.

7. The field synthesizer device of claim 6, wherein the shimming field and the at least one gradient field are generated parallel to the main field B₀.

8. The field synthesizer device of claim 7, wherein the shimming field and the at least one gradient field produce a z-component that alters the main field B₀.

9. The field synthesizer device of claim 1, wherein the shimming field data is calculated based on a pre-calculated shim field and a correction factor.

10. The field synthesizer device of claim 1, wherein the gradient field data is calculated based on a spatial filtering component and a pulse sequence component.

11. The field synthesizer device of claim 1, wherein the shimming field is generated by:
selecting a first subset of electromagnets in the first array and a second subset of electromagnets in the second array;
determining, using the shimming field data, a current level for each electromagnet in the first subsets of electromagnets;
determining, using the shimming field data, a current level for each electromagnet in the second subsets of electromagnets; and
applying the current levels to each electromagnet in the first and second subsets of electromagnets causing the first and second arrays to generate the shimming field.

12. The field synthesizer device of claim 1, wherein the at least one gradient field is generated by:
selecting a first subset of electromagnets in the first array and a second subset of electromagnets in the second array;
determining, using the gradient field data, a current level for each electromagnet in the first subsets of electromagnets;
determining, using the gradient field data, a current level for each electromagnet in the second subsets of electromagnets; and
applying the current level to each electromagnet in the first and second subsets of electromagnets causing the first and second arrays to generate the at least one gradient field.

13. The field synthesizer device of claim 1, wherein the plurality of electromagnets of the first array use the electric current to generate a first gradient field.

14. The field synthesizer device of claim 13, wherein the electric current is used to activate and set a polarity to NORTH for a first electromagnet of the plurality of electromagnets of the first array.

15. The field synthesizer device of claim 14, wherein the electric current is used to activate and set a polarity to SOUTH for a second electromagnet of the plurality of electromagnets of the first array.

16. The field synthesizer device of claim 15, wherein the plurality of electromagnets of the second array use the electric current to generate a second gradient field.

17. The field synthesizer device of claim 16, wherein the electric current is used to activate and set a polarity to SOUTH for a first electromagnet of the plurality of electromagnets of the second array.

18. The field synthesizer device of claim 17, wherein the electric current is used to activate and set a polarity to NORTH for a second electromagnet of the plurality of electromagnets of the second array.

19. The field synthesizer device of claim 1, wherein the plurality of electromagnets of the first and second arrays comprises a plurality of solenoids.

20. The field synthesizer device of claim 19, wherein each of the plurality of solenoids is wound around an iron core or other magnetic material.
